(19) United States
(12) Patent Application Publication
(10) Pub. No.: US 2018/0265964 A1
(43) Pub. Date: Sep. 20, 2018

(54) COLLIMATOR AND PROCESSING APPARATUS

(71) Applicant: Kabushiki Kaisha Toshiba, Minato-ku (JP)

(72) Inventors: Shiguma KATO, Yokohama (JP); Takahiro Terada, Yokohama (JP); Masakatsu Takeuchi, Obu (JP); Keita Koizumi, Yatomi (JP); Yoshinori Tokuda, Yokohama (JP)

(73) Assignee: Kabushiki Kaisha Toshiba, Minato-ku (JP)

(21) Appl. No.: 15/913,952

(22) Filed: Mar. 7, 2018

(30) Foreign Application Priority Data
Mar. 17, 2017 (JP) 2017-053313

(51) Int. Cl. C23C 14/54

(52) U.S. Cl. CPC C23C 14/54; C23C 14/34

(57) ABSTRACT

According to one embodiment, a collimator includes peripheral openings that extend between a grid region and a peripheral frame, are larger in size than unit through-holes, and penetrate through the collimator in a first direction. The peripheral openings include first peripheral openings located between first end walls and the peripheral frame.

### CROSS-REFERENCE TO RELATED APPLICATIONS

This application is based upon and claims the benefit of priority from Japanese Patent Application No. 2017-053313, filed on Mar. 17, 2017, the entire contents of which are incorporated herein by reference.

### FIELD

Embodiments described herein relate generally to a collimator and a processing apparatus.

### BACKGROUND

Conventionally, processing apparatuses such as sputtering apparatuses including collimators have been known.

It is beneficial to provide a collimator and a processing apparatus having novel structures with less inconvenience which can reduce variation in film thickness depending on positions on an object to process, for example.

### BRIEF DESCRIPTION OF THE DRAWINGS

FIG. 1 is a schematic and exemplary cross-sectional view of a processing apparatus according to an embodiment;

FIG. 2 is a schematic and exemplary plan view of a collimator according to a first embodiment;

FIG. 3 is a schematic and exemplary plan view of a collimator according to a second embodiment;

FIG. 4 is a schematic and exemplary plan view of a collimator according to a third embodiment;

FIG. 5 is a schematic and exemplary plan view of a collimator according to a fourth embodiment;

FIG. 6 is a schematic and exemplary plan view of a collimator according to a first modification;

FIG. 7 is a schematic and exemplary plan view of a collimator according to a second modification;

FIG. 8 is a schematic and exemplary plan view of a collimator according to a third modification; and

FIG. 9 is a schematic and exemplary plan view of a collimator according to a fourth modification.

### DETAILED DESCRIPTION

In general, according to one embodiment, a collimator includes a first face, a second face, a peripheral frame, a grid region, and first end walls. The first face intersects with a first direction. The second face is opposite to the first face, and intersects with the first direction. The grid region is a region in which unit frames are arranged along the first face and the second face between both ends of the peripheral frame in a second direction intersecting with the first direction. The unit frames surround unit through-holes penetrating through the collimator in the first direction. First end walls are positioned at both ends of the grid region in a third direction intersecting with the first direction and the second direction. The first end walls connect both ends of the grid region in the second direction. The grid region and the peripheral frame are provided with peripheral openings in-therebetween, and the peripheral openings are larger in size than the unit through-holes and penetrate through the collimator in the first direction. The peripheral openings include first peripheral openings located between the first end walls and the peripheral frame.

Exemplary embodiments of a collimator and a processing apparatus will now be disclosed. Configurations and control (technical features) of the embodiments provided below and operations and results (effects) produced by the configurations and control are only exemplary. In the drawings, directions V1, H2, and H3 are defined for the purpose of illustration. The direction V1 is a vertical direction (gravity direction), and the directions H2 and H3 are horizontal directions. The directions V1, H2, and H3 are perpendicular to one another.

The following embodiments include same or similar components. These components will be represented by the common reference numerals and redundant description thereof may be omitted below.

### First Embodiment

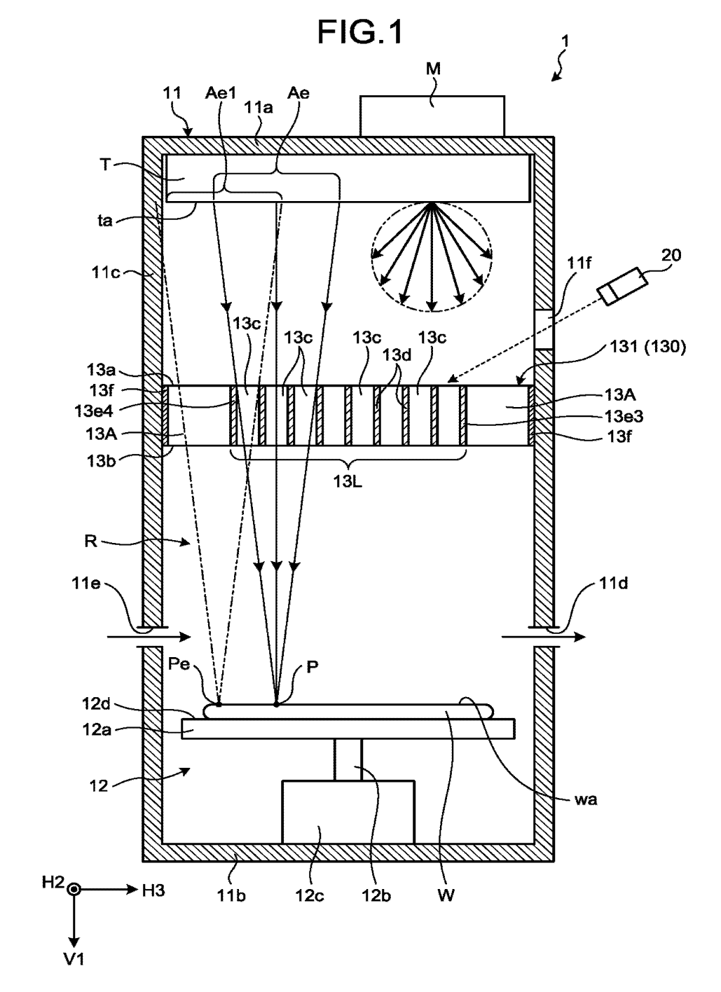

FIG. 1 is a cross-sectional view of a sputtering apparatus 1. The sputtering apparatus 1 forms (deposits) a film of metal particles on the surface of a wafer W, for example. The sputtering apparatus 1 is one example of a processing apparatus, and may be referred to as a film forming apparatus or a deposition apparatus. The wafer W is an example of an object to be processed, and may be referred to as an object.

The sputtering apparatus 1 includes a chamber 11. The chamber 11 has a substantially cylindrical shape around a central axis along the direction V1, and has a top wall 11a, a bottom wall 11b, and a circumferential wall 11c (side wall). The top wall 11a and the bottom wall 11b stand perpendicular to the direction V1 and extend in the directions H2 and H3. A generatrix of the circumferential wall 11c is along the direction V1. The chamber 11 defines a substantially cylindrical space as a processing chamber R. The sputtering apparatus 1 is installed with the central axis (the direction V1) of the chamber 11 extending in the vertical direction. The chamber 11 is an example of a container.

A target T can be placed on the top wall 11a in the processing chamber R of the sputtering apparatus 1. The target T is supported by the top wall 11a through a backing plate, for example. The target T generates metal particles. The target T can be referred to as a particle emitter or a particle generator. The top wall 11a or the backing plate can be referred to as an emitter mount.

A magnet M can be placed on the top wall 11a outside the processing chamber R of the sputtering apparatus 1. The target T generates metal particles from a region near the magnet M.

A stage 12 is provided near the bottom wall 11b in the processing chamber R of the sputtering apparatus 1. The stage 12 supports the wafer W. The stage 12 includes a plate 12a, a shaft 12b, and a support 12c. The plate 12a has a disc shape having a face 12d perpendicular to the direction V1, for example. The plate 12a supports the wafer W on the face 12d such that a face wa of the wafer W is along a plane perpendicular to the direction V1. The shaft 12b protrudes from the support 12c in a direction opposite to the direction V1, and is connected to the plate 12a. The plate 12a is supported by the support 12c through the shaft 12b. The support 12c can change the position of the shaft 12b in the direction V1. For changing the position in the direction V1, the support 12c may include a mechanism capable of changing a fixing position (holding position) of the shaft 12b or may include an actuator including a motor or a rotation to linear motion converting mechanism capable of electrically changing the position of the shaft 12b in the direction V1. A change in the position of the shaft 12b in the direction V1 results in a change in the position of the plate 12a in the direction V1. The positions of the shaft 12b and the plate 12a can be set in multiple steps or in a non-step manner (continuously variable). The stage 12 (plate 12a) is an example of an object mount. The stage 12 can be referred to as an object support, a position changer, or a position adjuster.

A collimator 130 is disposed between the top wall 11a and the stage 12. The collimator 130 is supported by the circumferential wall 11c of the chamber 11. The collimator 130 has a substantially disc shape having an upper face 13a, a lower face 13b opposite to the upper face 13a, and a cylindrical circumferential wall 13f. The upper face 13a and the lower face 13b are perpendicular to the direction V1, and extends two-dimensionally in the directions H2 and H3. The thickness direction of the collimator 130 corresponds to the direction V1. The collimator 130 is placed in the chamber 11 with substantially no gap between the outer circumference of the circumferential wall 13f and the inner circumference of the circumferential wall 11c of the chamber 11. The upper face 13a is an example of a first face, and the lower face 13b is an example of a second face. The direction V1 is an example of a first direction. The circumferential wall 13f is an example of a peripheral frame and an edge.

The collimator 130 has a plurality of through-holes 13c extending between the upper face 13a and the lower face 13b in the direction V1. The through-holes 13c are open toward the target T, that is, toward the top wall 11a and also open toward the wafer W, that is, toward the stage 12, and extend in the direction V1.

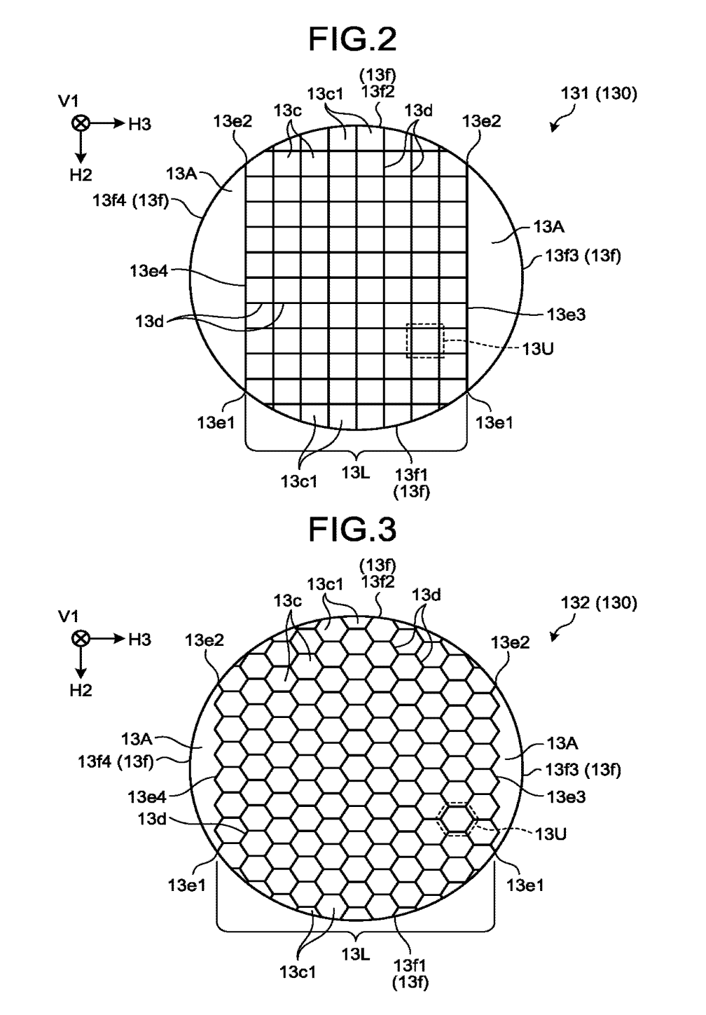

FIG. 2 is a plan view of a collimator 131 (130). The through-holes 13c have a polygonal cross-sectional shape, and have a square shape (quadrangular shape) in the present embodiment as illustrated in FIG. 2. The through-holes 13c are each surrounded by four vertical walls 13d standing in the direction V1. As illustrated in FIG. 2, in the collimator 131 as viewed in the direction V1, four vertical walls 13d constitute a square (quadrangular) unit frame 13U surrounding each through-hole 13c, and two or more unit frames 13U are closely arranged two-dimensionally, forming a grid region 13L. The through-holes 13c are an example of unit through-holes. The through-holes 13c are an example of inner circumferential surfaces of the unit frames 13U. The vertical walls 13d can also be referred to as walls.

As illustrated in FIG. 2, the grid region 13L extends across the collimator 131 between ends 13f1 and 13f2 (both ends) in the direction H2. the grid region 13L and the circumferential wall 13f (the ends 13f1 and 13f2) are provided at their connections with end through-holes 13c1 having a different size (cross-sectional area or opening area) from the through-holes 13c and end frames 13d1 surrounding the end through-holes 13c1. A region including the end frames 13d1 can also be referred to as an end region. The end through-holes 13c1 have a size smaller than the through-holes 13c in the present embodiment, however, may have a larger size than the through-holes 13c. The end through-holes 13c1 (the end regions) extend between the grid region 13L and the circumferential wall 13f (the peripheral frames), that is, at the connections therebetween and they are different from openings 13A (peripheral openings) between the grid region 13L and the circumferential wall 13f.

Meanwhile, the openings 13A extend between end walls 13e3 and 13e4 of the grid region 13L in the direction H3 and ends 13f3 and 13f4 of the collimator 131 in the direction H3, respectively. The end walls 13e3 and 13e4 connect the ends 13f1 and 13f2 (both ends), and extend straight in the direction H2 along the sides of the unit frames 13U. The openings 13A are located adjacent to the end walls 13e3 and 13e4 of the grid region 13L outside the grid region 13L, and extend in the direction H2. In addition, the openings 13A are larger in size than the through-holes 13c, extending between ends 13e1 and 13e2 (one end and the other end) of the respective end walls 13e3 and 13e4 in the direction H2. The openings 13A are an example of first peripheral openings (peripheral openings). The direction H2 is an example of a second direction, and the direction H3 is an example of a third direction.

The flow of particles is straightened in the direction V1 through the through-holes 13c extending in the direction V1 as described above. The collimator 130 is thus referred to as a flow straightener or a flow straightening member. The grid region 13L having the through-holes 13c can be referred to as a flow straightening part.

The circumferential wall 11c, for example, of the chamber 11 is provided with an outlet 11d. A pipe (not illustrated) extends from the outlet 11d and connects to a suction pump (vacuum pump; not illustrated), for example. By the operation of the suction pump, gas is discharged from the processing chamber R through the outlet 11d, which lowers the pressure in the processing chamber R. The suction pump is capable of sucking gas until the processing chamber R is placed substantially in a vacuum state.

The circumferential wall 11c, for example, of the chamber 11 is provided with an inlet 11e. A pipe (not illustrated) extends from the inlet 11e and connects to a tank (not illustrated), for example. The tank contains inert gas such as argon gas, for example. The inert gas in the tank can be introduced into the processing chamber R.

The circumferential wall 11c, for example, of the chamber 11 includes a transparent window 11f. The collimator 130 can be captured through the window 11f by a camera 20 installed outside of the chamber 11. The condition of the collimator 130 can be checked from the images captured by the camera 20 through image processing. The transparent window 11f may be covered with a detachable or openable lid, cover, or door. In addition, the circumferential wall 11c may have an opening (a through-hole) instead of the transparent window 11f, and may be provided with a lid that can open or close the opening. The lid, the cover, or the door can cover the window 11f or the opening during operation of the sputtering apparatus 1 and open the window 11f or the opening during non-operation of the sputtering apparatus 1, for example.

The sputtering apparatus 1 having the above structure ionizes the argon gas introduced into the processing chamber R by applying voltage to the target T, which generates plasma. The argon ions collide with the target T, which causes particles of a metal material (a film material) of the target T to fly from a bottom face ta of the target T, for example. The target T emits particles in this manner.

The flying directions of the particles from the bottom face ta of the target T are distributed according to the cosine law (Lambert's cosine law). Specifically, the particles flying from a certain point on the bottom face ta of the target T fly most in the normal direction (vertical direction or direction V1) to the bottom face ta. Thus, the normal direction is an example of the direction in which the target T placed on the top wall 11a or the backing plate (emitter mount) emits at least one particle. The number of particles flying in a direction at an angle θ with respect to (intersecting at an angle with) the normal direction is approximately proportional to a cosine (cos θ) of the number of particles flying in the normal direction.

The particles are microparticles of the metal material of the target T. The particles may be particles of matter such as molecules, atoms, atomic nuclei, elementary particles, or vapor (vaporized material). The particles may include positive ions such as positively charged copper ions.

As illustrated in FIG. 1, particles flying from a region Ae of the bottom face ta of the target T are mainly deposited on a point P on the face wa of the wafer W. The vertical walls 13d of the collimator 131 (130) block the particles from traveling in a diagonal direction at an angle exceeding a predetermined angle, thus, the size of the region Ae is defined by specifications such as the size or height (thickness) of the through-holes 13c of the collimator 131. Supposed that the vertical walls 13d of the unit frames 13U, instead of the openings 13A in the present embodiment, are provided at both ends of the collimator 131 in the direction H3, the particles can reach a point Pe at the end of the wafer W from the target T only through the area indicated by the chain double-dashed line in FIG. 1. This makes a region Ae1 of the bottom face ta of the target T from which particles fly toward the point Pe on the end of the wafer W smaller than the region Ae. In this case, the film thickness at the point Pe on the end of the wafer W may be smaller than at the center of the wafer W.

In the present embodiment, the collimator 131 (130) are thus provided with the openings 13A at both ends in the direction H3. Without the vertical walls 13d of the unit frames 13U in the openings 13A, a larger number of particles can reach the point Pe than with the vertical walls 13d in the openings 13A. Thus, by such a structure, the film at the ends (peripheries) of the wafer W can be made in larger thickness than that in related art, which prevents an increase in variation in the film thickness depending on the positions on the wafer W.

As described above, in the present embodiment, the openings 13A (first peripheral openings) of the collimator 131 (130) are located adjacent to the end walls 13e3 and 13e4 (first end walls) of the grid region 13L outside the grid region 13L, extend between the ends 13e1 and 13e2 (one end and the other end) of the end walls 13e3 and 13e4 in the direction H2 (second direction) along the end walls 13e3 and 13e4 in the direction H2, are larger in size than the through-holes 13c (unit through-holes), and penetrate through the collimator 131 in the direction V1. Thus, the openings 13A face the end walls 13e3 and 13e4 from the ends 13e1 (one end) to the ends 13e2 (the other end). This can prevent the film on the wafer W from becoming thinner in thickness at the point Pe on the end than at the center, leading to preventing an increase in variation in the film thickness depending on the positions on the wafer W.

In the present embodiment, the grid region 13L extends across the collimator 131 between the ends 13f1 and 13f2 (both ends) in the direction H2, and is relatively firmly supported by the ends 13f1 and 13f2 of the circumferential wall 13f with a desired width. Furthermore, the grid region 13L is connected to the circumferential wall 13f via the vertical walls 13d, which are shorter than the sides of the unit frames 13U and define the end through-holes 13c1 smaller than the through-holes 13c. As structured above, the grid region 13L can ensure desired rigidity and strength and desired position and orientation.

In addition, in the present embodiment, the through-holes 13c (unit through-holes) and the unit frames 13U have a quadrangular shape (polygonal shape) as viewed in the direction V1 (first direction). This makes it possible to provide the grid region 13L and the collimator 131 with simpler structures, and ensure desired rigidity and strength and thus desired position and orientation of the grid region 13L.

### Second Embodiment

FIG. 3 is a plan view of a collimator 132 according to the present embodiment. The sputtering apparatus 1 of FIG. 1 can include the collimator 132 instead of the collimator 131. The present embodiment is different from the first embodiment in the shape of the through-holes 13c (unit through-holes) and the unit frames 13U. Specifically, as illustrated in FIG. 3, the through-holes 13c and the unit frames 13U have a regular hexagonal shape (hexagonal shape). The through-holes 13c are each surrounded by six vertical walls 13d in the direction V1. As illustrated in FIG. 3, in the collimator 132 as viewed in the direction V1, six vertical walls 13d constitute a regular hexagonal (hexagonal) unit frame 13U surrounding a through-hole 13c, forming a grid region 13L in which the unit frames 13U are closely arranged two-dimensionally.

In the present embodiment as well, the grid region 13L extends across the collimator 132 between the ends 13f1 and 13f2 (both ends) in the direction H2.

The openings 13A extend between the end walls 13e3 and 13e4 of the grid region 13L in the direction H3 and the ends 13f3 and 13f4 of the collimator 132 in the direction H3, respectively. The end walls 13e3 and 13e4 each extend in the direction H2 along the sides of the hexagonal unit frames 13U in a zigzag manner.

Thus, in the present embodiment as well, the openings 13A (first peripheral openings) of the collimator 132 (130) are located adjacent to the end walls 13e3 and 13e4 (first end walls) of the grid region 13L outside the grid region 13L, extend between the ends 13e1 and 13e2 (one end and the other end) of the end walls 13e3 and 13e4 in the direction H2 (second direction) along the end walls 13e3 and 13e4 in the direction H2, are larger in size than the through-holes 13c (unit through-holes), and penetrate through the collimator 132 in the direction V1. Thus, the openings 13A face the end walls 13e3 and 13e4 from the ends 13e1 (one end) to the ends 13e2 (the other end). This can prevent the film from becoming thinner in thickness at the ends of the wafer W than at the center of the wafer W, and thus prevent an increase in variation in the film thickness depending on the positions on the wafer W.

In the present embodiment as well, the grid region 13L extends across the collimator 132 between the ends 13f1 and 13f2 (both ends) in the direction H2, and is relatively firmly supported by the ends 13f1 and 13f2 of the circumferential wall 13f with a desired width. The through-holes 13c (unit through-holes) and the unit frames 13U have a hexagonal shape. This makes it possible to provide the grid region 13L and the collimator 132 with simpler structures, and ensure desired rigidity and strength and thus desired position and orientation of the grid region 13L.

### Third Embodiment

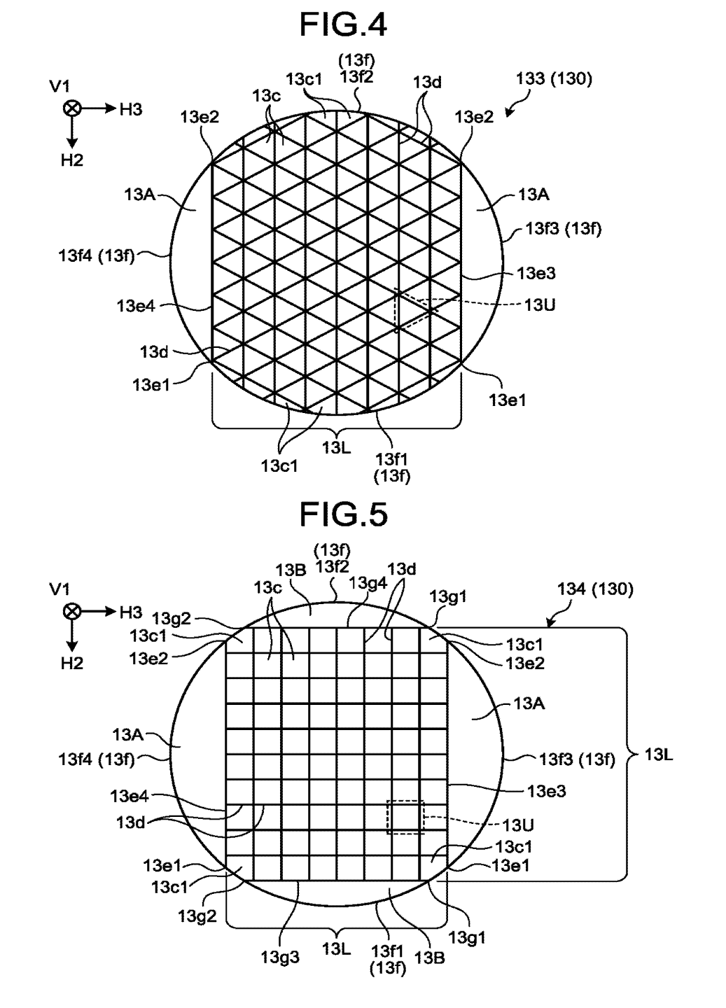

FIG. 4 is a plan view of a collimator 133 according to the present embodiment. The sputtering apparatus 1 of FIG. 1 can include the collimator 133 instead of the collimator 131. The present embodiment is different from the first and second embodiments in the shape of the through-holes 13c (unit through-holes) and the unit frames 13U. Specifically, as illustrated in FIG. 4, the through-holes 13c and the unit frames 13U have a regular triangular shape (triangular shape). The through-holes 13c are each surrounded by three vertical walls 13d in the direction V1. As illustrated in FIG. 4, in the collimator 133 as viewed in the direction V1, three vertical walls 13d constitute a regular triangular (triangular) unit frame 13U surrounding a through-hole 13c, forming a grid region 13L in which the unit frames 13U are closely arranged two-dimensionally.

In the present embodiment as well, the grid region 13L extends across the collimator 133 between the ends 13f1 and 13f2 (both ends) in the direction H2.

In addition, the openings 13A extend between the end walls 13e3 and 13e4 of the grid region 13L in the direction H3 and the ends 13f3 and 13f4 of the collimator 133 in the direction H3, respectively. The end walls 13e3 and 13e4 extend straight in the direction H2 along the sides of the unit frames 13U.

Thus, in the present embodiment as well, the openings 13A (first peripheral openings) of the collimator 133 (130) are located adjacent to the end walls 13e3 and 13e4 (first end walls) of the grid region 13L outside the grid region 13L, extend between the ends 13e1 and 13e2 (one end and the other end) of the end walls 13e3 and 13e4 in the direction H2 (second direction) along the end walls 13e3 and 13e4 in the direction H2, are larger in size than the through-holes 13c (unit through-holes), and penetrate through the collimator 133 in the direction V1. This can prevent the film from becoming thinner in thickness at the ends of the wafer W than at the center of the wafer W, and thus prevent an increase in variation in the film thickness depending on the positions on the wafer W.

In addition, in the present embodiment as well, the grid region 13L extends across the collimator 133 between the ends 13f1 and 13f2 (both ends) in the direction H2, and is relatively securely supported by the ends 13f1 and 13f2 of the circumferential wall 13f with a desired width. The through-holes 13c (unit through-holes) and the unit frames 13U have a triangular shape. This makes it possible to provide the grid region 13L and the collimator 133 with simpler structures, and ensure desired rigidity and strength and desired position and orientation of the grid region 13L.

### Fourth Embodiment

FIG. 5 is a plan view of a collimator 134 according to the present embodiment. The sputtering apparatus 1 of FIG. 1 can include the collimator 134 instead of the collimator 131. In the present embodiment, the shape of the through-holes 13c (unit through-holes) and the unit frames 13U is the same as that in the first embodiment.

In the present embodiment, however, the collimator 133 is provided with openings 13B extending between end walls 13g3 and 13g4 of the grid region 13L in the direction H2 and the ends 13f1 and 13f2 of the collimator 134 in the direction H2, respectively, in addition to the openings 13A in the first embodiment. The end walls 13g3 and 13g4 connect the ends 13f3 and 13f4 (both ends) of the collimator 134 in the direction H3, and extend straight in the direction H3 along the sides of the unit frames 13U. The openings 13B are an example of second peripheral openings (peripheral openings), and the end walls 13g3 and 13g4 are an example of second end walls. In the present embodiment as well, the grid region 13L is connected at the ends (corners or four corners) to the circumferential wall 13f via relatively short vertical walls 13d defining the end through-holes 13c1, which are smaller than the through-holes 13c. Thereby, the grid region 13L can ensure desired rigidity and strength.

In the present embodiment, the collimator 134 (130) is provided with the openings 13B (second peripheral openings) in addition to the openings 13A. The openings 13B are located adjacent to the end walls 13g3 and 13g4 (second end walls) of the grid region 13L outside the grid region 13L, extend between ends 13g1 and 13g2 (one end and the other end) of the end walls 13g3 and 13g4 in the direction H3 (third direction) along the end walls 13g3 and 13g4 in the direction H3, are larger in size than the through-holes 13c (unit through-holes), and penetrate through the collimator 134 in the direction V1. Thus, the openings 13B face the end walls 13g3 and 13g4 from the ends 13g1 (one end) to the ends 13g2 (the other end). This can prevent the film from becoming thinner in thickness at the end of the wafer W than at the center of the wafer W, and thus prevent an increase in variation in the film thickness depending on the positions on the wafer W. In addition, the area of the film having a thinner thickness than the rest of the film can be made smaller than that in the first to third embodiments. The shape of the through-holes 13c and the unit frames 13U of the collimator 134 having such openings 13B is not limited to being quadrangular but may be triangular or hexagonal, for example.

Modifications

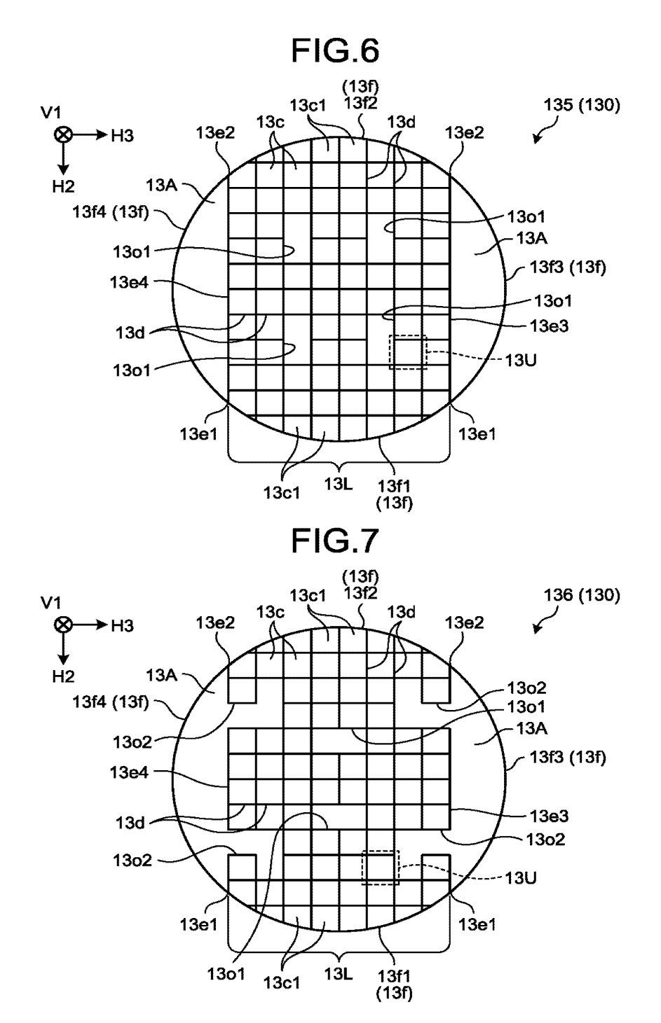

FIG. 6 is a plan view of a collimator 135 according to a first modification, and FIG. 7 is a plan view of a collimator 136 according to a second modification. The sputtering apparatus 1 of FIG. 1 can include the collimators 135 and 136 (130) instead of the collimator 131. In the present embodiment, the shape of the through-holes 13c (unit through-holes) and the unit frames 13U is the same as that in the first embodiment.

In the modification of FIG. 6, however, the grid region 13L includes openings 13o1 (inner openings) formed by mutually connecting through-holes 13c (unit through-holes). In the modification of FIG. 7, the grid region 13L includes, at the periphery, openings 13o2 (cutouts) formed by connecting at least one of one or more mutually connected through-holes 13c to the openings 13A, in addition to the openings 13o1. The openings 13o1 and 13o2 are each formed by removing the side (at least one of the sides of the unit frames 13U) located between the adjacent through-holes 13c. Such openings 13o1 and 13o2 may be able to help reduce variation in the film thickness on the wafer W. The shape of the through-holes 13c forming the openings 13o1 and 13o2 and the unit frames 13U are not limited to being quadrangular but may be triangular or hexagonal, for example. In addition, the specifications of the openings 13o1 including position, number, size, shape, and orientation are not limited to the examples of FIGS. 6 and 7.

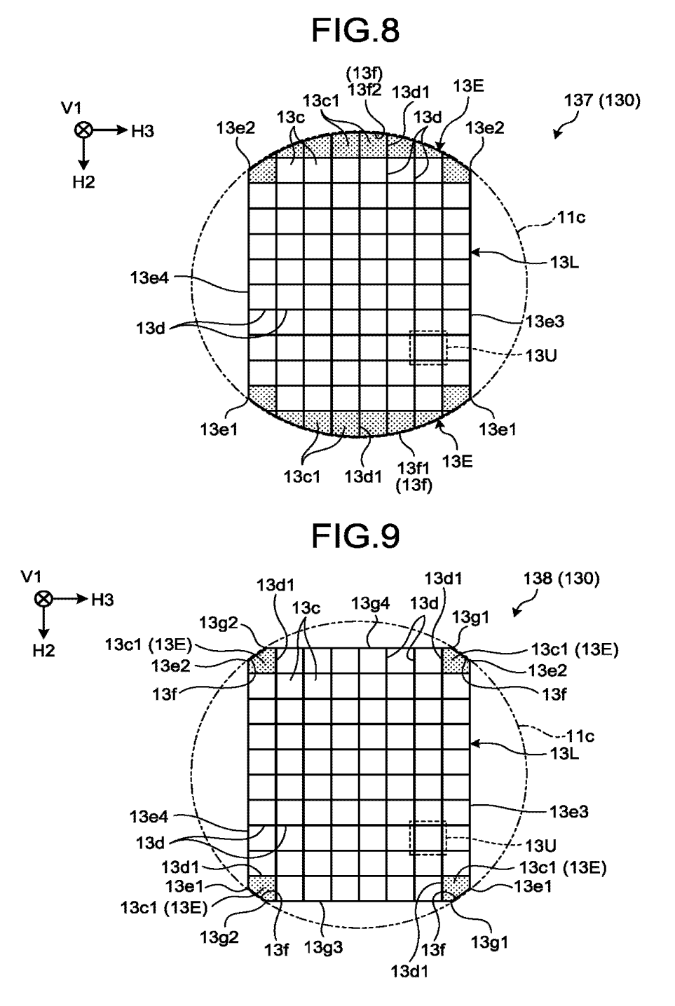

FIG. 8 is a plan view of a collimator 137 according to a third modification, and FIG. 9 is a plan view of a collimator 138 according to a fourth modification. The sputtering apparatus 1 of FIG. 1 can include the collimators 137 and 138 (130) instead of the collimator 131. In the present embodiment, the shape of the through-holes 13c (unit through-holes) and the unit frames 13U is the same as that in the first embodiment.

In the modifications of FIGS. 8 and 9, however, the circumferential wall 13f facing the inside of the circumferential wall 11c of the chamber 11 is divided. Specifically, at positions facing the end walls 13e3 and 13e4 (first end walls) and the end walls 13g3 and 13g4 (second end walls), there is no circumferential wall 13f facing the inside of the circumferential wall 11c of the chamber 11. The mutually separated circumferential walls 13f are an example of third end walls.

The collimators 137 and 138 both include end regions 13E between the grid region 13L and the arc-like circumferential walls 13f facing the circumferential wall 11c of the chamber 11. The end regions 13E include the end frames 13d1 surrounding the end through-holes 13c1. The end through-holes 13c1 are different in size (cross-sectional area or opening area) from the through-holes 13c (unit through-holes) and can be larger or smaller than the through-holes 13c. In FIGS. 8 and 9, the end regions 13E are represented by dot patterns. In the collimator 137 of FIG. 8, the plurality of (two) end regions 13E extend along the edges of the collimator 137 as viewed in the direction V1, and the end regions 13E each include a plurality of end frames 13d1. In the collimator 138 of FIG. 9, a plurality of (four) end regions 13E are arranged in the corners of the collimator 138 as viewed in the direction V1, and the end regions 13E each include one end frame 13d1.

In these modifications, the circumferential wall 13f or the end regions 13E are supported by the circumferential wall 11c of the chamber 11. As is clear in FIGS. 8 and 9, the collimator 137 or 138 is mounted in the chamber 11 with openings similar to the openings 13A and 13B of the above-described embodiments between the end walls 13e3, 13e4, 13g3, and 13g4 and the circumferential wall 11c of the chamber 11. Thus, these modifications can also attain effects similar to those of the above embodiments. According to these modifications, the collimators 137 and 138 can be made lighter in weight. In the modifications, the shape of the through-holes 13c and the unit frames 13U of the grid region 13L are not limited to being quadrangular but may be triangular or hexagonal, for example. In addition, the specifications of the end through-holes 13c1, the end frames 13d1, and the grid region 13L including positions, numbers, sizes, shapes, and orientations are not limited to the examples of FIGS. 8 and 9.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions. The configurations and forms of the embodiments can be partially replaced with each other. Furthermore, specifications including configurations and forms (structures, types, directions, shapes, sizes, lengths, widths, thicknesses, angles, numbers, positions, materials, and the like) can be changed as necessary. For example, the processing apparatus may be an apparatus such as a CVD apparatus other than the sputtering apparatus. In addition, the unit through-holes and the unit frames may have shapes other than those in the embodiments described above.

What is claimed is:

1. A collimator comprising:
a first face intersecting with a first direction;
a second face opposite to the first face, intersecting with the first direction;
a peripheral frame;
a grid region in which unit frames are arranged along the first face and the second face between both ends of the peripheral frame in a second direction intersecting with the first direction, the unit frames that surround unit through-holes penetrating through the collimator in the first direction; and
first end walls positioned at both ends of the grid region in a third direction intersecting with the first direction and the second direction, the first end walls connecting both ends of the grid region in the second direction, wherein
the grid region and the peripheral frame are provided with peripheral openings in-therebetween, the peripheral openings that are larger in size than the unit through-holes and penetrate through the collimator in the first direction, and
the peripheral openings include first peripheral openings located between the first end walls and the peripheral frame.

2. The collimator according to claim 1, further comprising:
second end walls positioned between both ends of the grid region in the second direction and connecting both ends of the grid region in the third direction, wherein
the peripheral openings include second peripheral openings located between the second end walls and the peripheral frame.

3. The collimator according to claim 1, wherein the grid region is provided with an inner opening formed by mutually connecting two or more of the unit through-holes.

4. The collimator according to claim 1, wherein cutouts connected with the peripheral openings are formed.

5. The collimator according to claim 1, wherein the unit through-holes have a polygonal shape as viewed in the first direction.

6. A processing apparatus comprising:
a container; and
the collimator according to claim 1 provided in the container.

7. A collimator comprising:
a first face intersecting with a first direction;
a second face opposite to the first face, intersecting with the first direction;
a plurality of third end walls spaced apart from each other in a direction intersecting with the first direction;
a grid region in which a plurality of unit frames are arranged adjacent to one another along the first face and the second face, the unit frames that surround unit through-holes penetrating through the collimator in the first direction; and
a plurality of end regions being positioned between the grid region and the third end walls and including one or more end frames that surround end through-holes, the end through-holes different in size from the unit through-holes and penetrating through the collimator in the first direction.

8. The collimator according to claim 7, wherein the end regions extend along an edge of the collimator as viewed in the first direction.

9. The collimator according to claim 7, wherein the end regions are located in corners of the collimator as viewed in the first direction.
